(19) United States
(12) Patent Application Publication
(10) Pub. No.: US 2006/0121723 A1
(43) Pub. Date: Jun. 8, 2006

(54) SEMICONDUCTOR PROCESS AND METHOD OF FABRICATING INTER-LAYER DIELECTRIC

(76) Inventors: Chin-Ta Su, Hsinchu (TW); Chin-Wei Liao, Hsinchu (TW); Lee-Jen Chen, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/904,947

(22) Filed: Dec. 7, 2004

(51) Int. Cl. H01L 21/4763; H01L 21/311; H01L 21/31

(52) U.S. Cl. 438/624; 438/697; 438/626; 438/761

(57) ABSTRACT

A semiconductor process is described. On a dielectric layer, a planarization process is performed and then a material layer is formed. Next, an opening is formed in the material layer and the dielectric layer. In a subsequent thermal process, the material layer is converted into a material layer with compressive stress so as to prevent defect from forming in the dielectric layer. A method of fabricating an inter-layer dielectric is also described. A dielectric layer is first formed on a substrate, and a planarization process is then performed on the dielectric layer. A material layer is subsequently formed on the dielectric layer. After a thermal process, the material layer is converted into a material layer with compressive stress. Therefore, formation of cracks in the dielectric layer can be prevented, and device reliability and yield can be increased.

### BACKGROUND OF THE INVENTION

1. Field of the Invention

The present invention relates to a semiconductor process and a method of fabricating an inter-layer dielectric, and more particularly to a semiconductor process and a method of fabricating an inter-layer dielectric to prevent formation of cracks in the inter-layer dielectric.

2. Description of the Related Art

The dielectric layer used between conductive layers can be generally classified as inter-layer dielectric (ILD) and inter-metal dielectric layer (IMD). Wherein, the inter-layer dielectric is mainly used for insulating a poly-silicon layer (poly-Si) from the first metal layer (M1), or used in a dynamic random access memory (DRAM) for separating the third poly-silicon layer (poly-3) and the forth poly-silicon layer (poly-4).

With the increase in the extent of integration of integrated circuits, the sizes of circuit units tend to be smaller and smaller, and the gaps between the circuit units are also reduced. A material of borophosphosilicate glass (BPSG) with desirable mobility is thus used for making the inter-layer dielectric, and thus, under high temperature, the BPSG can be fed into the gaps between circuit units because of its thermal flow property.

To avoid short in a circuit unit, a method of low-pressure chemical vapor deposition (LPCVD) is usually used during a conventional semiconductor process to form a silicon nitride layer as a spacer on a substrate. A BPSG layer is then formed and planarized as an inter-layer dielectric layer; and, after the planarization step, a silicon oxide layer is usually deposited on the BPSG layer for certain reasons, such as, prevention of scratches or control of ILD thickness. However, when the temperature in the subsequent processes excesses the glass transfer temperature of the BPSG layer, the BPSG layer will be brought to a re-flow state, and, on the other hand, the silicon oxide layer has stress variation as heated, which often causes formation of cracks in the inter-layer dielectric.

To solve the problems of cracking in the inter-layer dielectric occurred in the conventional processes, a densification step is usually performed after the formation of all inter-layer dielectric layers include the BPSG layer, the silicon oxide layer and the anti-reflection layer. Additionally, extra annealing processes are usually required to prevent such cracks from forming.

As known from the above, in conventional semiconductor processes, the problems of cracking in the inter-layer dielectric adversely affect the reliability and yield of circuit units. On the other hand, the employment of extra thermal processes, which is required to solve the problems of cracking in the inter-layer dielectric, will increase the overall thermal budget and hence increase the production costs.

### SUMMARY OF THE INVENTION

In view of the above, the present invention is directed to provide a semiconductor process for solving the problems of cracks forming in an inter-layer dielectric so as to increase the reliability and yield of the circuit units and reduce the thermal budget of the fabricating process.

The present invention is also directed to provide a method of fabricating an inter-layer dielectric so as to avoid the problems of cracking in the inter-layer dielectric that would adversely affect the subsequent processes.

The present invention provides a semiconductor process. A substrate with a dielectric layer formed thereon is provided, a planarization process is performed to the dielectric layer, and a material layer is then formed on the dielectric layer. An opening is formed in the dielectric layer. Afterwards, a thermal process is performed to convert the material layer into one with compressive stress so as to prevent defects from forming in the dielectric layer.

According to one preferred embodiment of the semiconductor process, the method of forming the material layer on the above-mentioned dielectric layer is, for example, a chemical vapor deposition method. Wherein, the material layer is made of, for example, silicon oxide, silicon nitride, or silicon oxynitride. Moreover, the foregoing material layer, prior to the thermal process, has desirable compressive stress or tensile stress.

In the embodiment, the dielectric layer is made of silicon oxide, silicon nitride, or silicon oxynitride. Wherein, the silicon nitride layer includes a phosphosilicate glass (PSG) layer, a borosilicate glass (BSG) layer, a borophospho-silicate glass (BPSG) layer or an undoped silicate glass layer.

In the embodiment, the thermal process is of, for example, thermal furnace tempering or rapid thermal annealing. The planarization process to planarize the dielectric layer is, for example, a chemical mechanical polishing process. An anti-reflection layer is formed, after the formation of the material layer on the dielectric layer, on the material layer.

The present invention further provides a method of fabricating an inter-layer dielectric. A substrate is provided, and a dielectric layer is then formed thereon. A planarization process is then performed on dielectric layer. Next, a material layer is formed on the dielectric layer, wherein, after a thermal process, the material layer is converted to a material layer with compressive stress to prevent defects from forming in the dielectric layer.

According to one preferred embodiment of the method of fabricating the inter-layer dielectric, the substrate is, for example, a silicate substrate. In addition, the dielectric layer is formed on the substrate via, for example, chemical vapor deposition.

As known from the above, the present invention provides that the material layer is formed on the dielectric layer and is treated through a thermal process to have compressive stress, such that the problem of formation of cracks in the inter-layer dielectric, which would have adverse effects in the subsequent processes, can be avoided. In addition, the present invention, unlike the prior art, does not require extra thermal processes to avoid the problem of cracking. Therefore, thermal budget can be reduced, and the device reliability and yield can be increased.

It is to be understood that both the foregoing general description and the following detailed description are exemplary, and are intended to provide further explanation of the invention as claimed.

### BRIEF DESCRIPTION OF THE DRAWINGS

FIGS. 1A to 1C are cross-sectional views showing a method of fabricating an inter-layer dielectric according to an embodiment of the present invention.

FIGS. 2A to 2E are cross-sectional views showing a semiconductor process according to another embodiment of the present invention.

### DESCRIPTION OF THE PREFERRED EMBODIMENTS

The following description to the preferred embodiments of the present invention, as illustrated in the accompanied drawings, are set forth, for the purpose of explanation and not limitation, to provide a thorough understanding of the present invention.

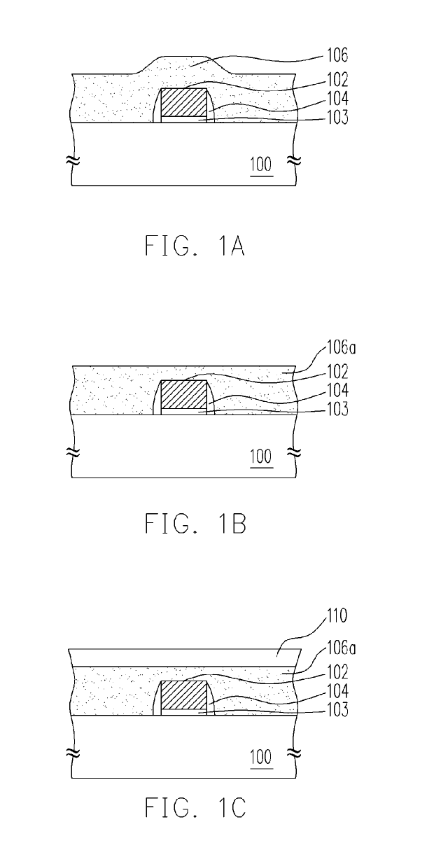

As mentioned above, the present invention provides a method of fabricating an inter-layer dielectric. FIGS. 1A to 1C illustrate the method of fabricating an inter-layer dielectric according to one embodiment of the present invention.

Referring to FIG. 1A, a substrate 100 is provided, which is a silicate substrate, and the substrate 100 has a gate 102, a gate oxide 103 and a spacer 104 formed thereon. A dielectric layer 106 is then formed on the substrate 100, wherein the dielectric layer 106 is, for example, a silicon oxide layer, a silicon nitride layer or a silicon oxynitride layer, and further, the silicon oxide layer is, for example, a phosphosilicate glass (PSG) layer, a borosilicate glass (BSG) layer, a borophosphosilicate glass (BPSG) layer or an undoped silicate layer. In addition, the dielectric layer 106 is formed via, for example, chemical vapor deposition. Note that the surface of the dielectric layer 106 is uneven because of the manner of direct deposition of the silicon oxide layer, the silicon nitride layer or the silicon oxynitride layer to form the dielectric layer 106.

Subsequently, as shown in FIG. 1B, a planarization process is performed on the dielectric layer 106a. The planarization process is performed via, for example, chemical mechanical polishing, so as to planarize the dielectric layer 106.

Referring further to FIG. 1C, a material layer 110 is formed on the dielectric layer 106a. The material layer 110 is formed via, for example, chemical vapor deposition, and is made of, for example, silicon oxide, silicon nitride, or silicon oxynitride. In addition, the material layer 110, prior to any treatment, can have compressive stress or tensile stress, but after a thermal process, the material layer 110 is converted to a material layer with compressive stress.

As known from the above, the present invention provides that the material layer 110 is formed on the dielectric layer 106a and is treated through a thermal process to have compressive stress, such that the problem of formation of cracks in the inter-layer dielectric, which would have adverse effects in the subsequent processes, can be avoided.

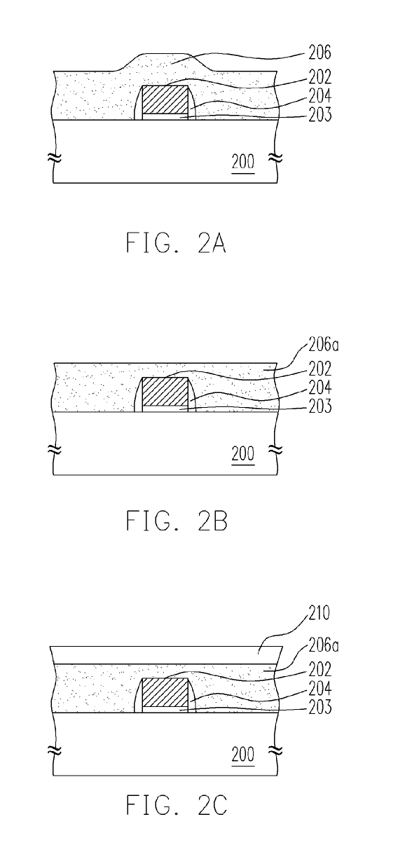

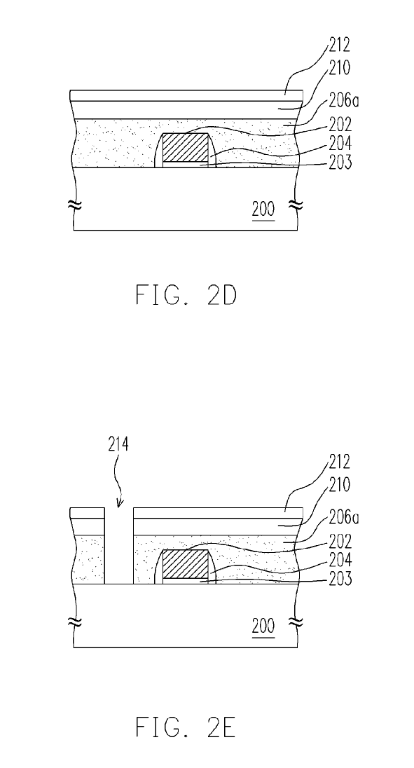

The foregoing method of fabricating the inter-layer dielectric can also be applied in a semiconductor process. An embodiment of such semiconductor process is shown in FIGS. 2A to 2E, which is further described in the following.

Referring to FIGS. 2A to 2C, since the methods and relevant materials shown in FIGS. 2A to 2C are similar to those shown in FIGS. 1A to 1C, like reference numbers are used to indicate the same or like elements. Thus, for the substrate 200, gate 202, gate oxide 203, spacer 204, dielectric layer 206/206a, and material layer 210 in FIGS. 2A to 2C, detailed descriptions are omitted here for simplicity and clarity.

After the material layer 210 is formed on the dielectric layer 206a as shown in FIG. 2C, a thermal process is performed to convert the material layer 210 into a material layer with compressive stress. The thermal process is of, for example, thermal furnace tempering or rapid thermal annealing. Since the material layer 210 is converted to a material layer with compressive stress, the problem of cracking of the prior art processes can be avoided, and hence device reliability and yield can be increased.

Referring to FIG. 2D, an anti-reflection layer 212 is further formed on the material layer 210 for the subsequent photolithographic process. Wherein, the anti-reflection layer 212 is, for example, an organic bottom anti-reflection layer or an inorganic bottom anti-reflection layer.

Referring further to FIG. 2E, an opening 214 is formed in the dielectric layer 206a, the material layer 210 and the anti-reflection layer 212. Wherein, the opening 214 is formed in a method of, for example, forming a photoresist layer on the anti-reflection layer 212 via spin-spraying, and then forming the opening 214 in the dielectric layer 206a, the material layer 210 and the anti-reflection layer 212 via photolithographic and etching processes.

As shown in the foregoing preferred embodiment of the present invention, after the formation of the anti-reflection layer 212 on the material layer 210, the densification step, as required in the prior art process, is not required to avoid the problem of cracking in the inter-layer dielectric. In addition, the extra annealing processes, as required in the prior art process, are also no longer required to avoid the problem of cracking. Thus, thermal budget of the process can be reduced.

To conclude, the present invention has advantages as follows. (1) The method of fabricating the inter-layer dielectric of this invention can be used to avoid the problem of formation of cracks in the inter-layer dielectric, which would affect the subsequent processes. (2) The semiconductor process of this invention can be employed to avoid the problem of formation of cracks in the inter-layer dielectric, so that device reliability and yield can be increased. (3) In this invention, the extra thermal processes, which are required in a conventional process to avoid the problem of cracking, are no longer necessary, and hence thermal budget can be reduced.

It will be apparent to those skilled in the art that various modifications and variations can be made to the process/method of the present invention without departing from the scope or spirit of the invention. In view of the foregoing, it is intended that the present invention covers modifications and variations of this invention provided they fall within the scope of the following claims and their equivalents.

What is claimed is:

1. A semiconductor process, comprising:
providing a substrate having a dielectric layer formed thereon;
performing a planarization process to the dielectric layer;
forming a material layer on the dielectric layer;
forming an opening in the dielectric layer and the material layer; and
performing a thermal process to make the material layer to have compressive stress.

2. The semiconductor process according to claim 1, wherein the step of forming the material layer comprises chemical vapor deposition.

3. The semiconductor process according to claim 1, wherein the material layer is made of silicon oxide, silicon nitride, or silicon oxynitride.

4. The semiconductor process according to claim 1, wherein the material layer, prior to the thermal process, possesses compressive stress or tensile stress.

5. The semiconductor process according to claim 1, wherein the dielectric layer is a layer of silicon oxide, silicon nitride, or silicon oxynitride.

6. The semiconductor process according to claim 5, wherein the silicon oxide layer is made of phosphosilicate glass (PSG), borosilicate glass (BSG), borophosphosilicate glass (BPSG) or undoped silicate glass.

7. The semiconductor process according to claim 1, wherein the thermal process is performed via thermal furnace tempering or rapid thermal annealing.

8. The semiconductor process according to claim 1, wherein the process of planarization comprises chemical mechanical polishing.

9. The semiconductor process according to claim 1, further comprising a step of forming a anti-reflection layer on the material layer, after the formation of the material layer.

10. A method of fabricating a inter-layer dielectric, comprising:
providing a substrate;
forming a dielectric layer on the substrate;
performing a planarization process to the dielectric layer; and
forming a material layer on the dielectric layer, wherein the material layer, after a thermal process, is converted to have compressive stress so as to prevent defects from forming in the dielectric layer.

11. The method of fabricating the inter-layer dielectric according to claim 10, wherein the substrate is made of silicate.

12. The method of fabricating the inter-layer dielectric according to claim 10, wherein the dielectric layer is made of silicon oxide, silicon nitride, or silicon oxynitride.

13. The method of fabricating the inter-layer dielectric according to claim 12, wherein the silicon oxide layer is made of phosphosilicate glass (PSG), borosilicate glass (BSG), borophosphosilicate glass (BPSG) or undoped silicate glass.

14. The method of fabricating the inter-layer dielectric according to claim 10, wherein the dielectric layer is formed on the substrate via chemical vapor deposition.

15. The method of fabricating the inter-layer dielectric according to claim 10, the material layer is formed on the dielectric layer via chemical vapor deposition.

16. The method of fabricating the inter-layer dielectric according to claim 10, wherein the material layer is made of silicon oxide, silicon nitride, or silicon oxynitride.

17. The method of fabricating the inter-layer dielectric according to claim 10, wherein the material layer, prior to the thermal process, possesses compressive stress or tensile stress.

18. The method of fabricating the inter-layer dielectric according to claim 10, wherein the step of planarization comprises chemical mechanical polishing.
